(19) United States
(12) Patent Application Publication
(10) Pub. No.: US 2008/0220603 A1
(43) Pub. Date: Sep. 11, 2008

(54) METHOD OF MANUFACTURING SEMICONDUCTOR DEVICE

(76) Inventors: Takashi Fukushima, Yokohama-Shi (JP); Toshiyuki Sasaki, Yamato-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/034,754

(22) Filed: Feb. 21, 2008

(30) Foreign Application Priority Data
Feb. 23, 2007 (JP) 2007-44053

(51) Int. Cl. H01L 21/28

(52) U.S. Cl. 438/591; 257/E21.177

(57) ABSTRACT

An embodiment of the present invention is a method of manufacturing a semiconductor device, for forming transistors of first and second conductivity types in first and second regions on a substrate respectively. The method includes: depositing a gate insulator and a sacrificial layer ranging from the first region to the second region; removing the sacrificial layer from the first region; depositing a first gate electrode layer, on the gate insulator exposed in the first region, and on the sacrificial layer remaining in the second region; removing the first gate electrode layer and the sacrificial layer from the second region; depositing a second gate electrode layer on the gate insulator exposed in the second region; forming the transistor of the first conductivity type including the gate insulator and the first gate electrode layer; and forming the transistor of the second conductivity type including the gate insulator and the second gate electrode layer.

### CROSS-REFERENCE TO RELATED APPLICATION

This application is based upon and claims the benefit of priority from the prior Japanese Patent Application No. 2007-44053, filed on Feb. 23, 2007, the entire contents of which are incorporated herein by reference.

### BACKGROUND OF THE INVENTION

1. Field of the Invention

The present invention relates to a method of manufacturing a semiconductor device.

2. Background Art

In recent years, due to the decrease of supply voltage of an LSI, the thickness of a gate insulator tends to be reduced. However, a conventional FET structure, which includes a gate insulator of silicon oxide and a gate electrode of polysilicon, has a problem that, when a depletion layer is formed in the gate electrode, the effective thickness of the gate insulator increases. Therefore, in recent years, a MISFET (Metal Insulator Semiconductor Field Effect Transistor), which includes a gate electrode formed of metal material, attracts attention. Such a MISFET has an advantage that a depletion layer is not formed in the gate electrode.

Further, due to the tendency that the function and the performance of an LSI are improved, there is an increasing interest in a CMISFET (CMIS), which includes an NMISFET (NMIS) and a PMISFET (PMIS) mounted on an identical substrate. Since the work function of a metal gate cannot be controlled by ion implantation unlike the work function of a polysilicon gate, it is necessary to use different metal materials for the NMIS and the PMIS. Such a dual metal gate is formed by, for example, depositing metal material for an NMIS electrode, and then depositing metal material for a PMIS electrode. In this case, the metal material for the NMIS electrode is deposited not only in an NMIS region but also in a PMIS region, by the former deposition process. Therefore, in this case, it is necessary to remove the metal material for the NMIS electrode from the PMIS region, before the latter deposition process (L. Hsu, et al., 2006 Dry Process International Symposium, p 13).

In the removal of the metal material, it is likely that a gate insulator is damaged and the thickness of the gate insulator is reduced by over-etching. This is because it is difficult to obtain the etching selectivity of the metal material to the gate insulator, when the metal material is selected from a viewpoint of work function. It is likely that the damage to the gate insulator and the reduction in the thickness of the gate insulator cause decrease in mobility of a transistor due to its interface state, and change in a characteristic of the transistor. This may deteriorate the performance of the transistor in the CMIS.

Moreover, in some case, different gate insulators are used for the NMIS and the PMIS, or the same gate insulator is formed twice for the NMIS and the PMIS dividedly. In this case, a process for removing a gate insulator from a substrate is necessary. In the removal of the gate insulator, it is likely that the substrate is damaged and the thickness of the substrate is reduced by over-etching. This problem is serious, in particular, when the gate insulator is a high-k layer (a high-permittivity insulating layer). This is because it is difficult to obtain the etching selectivity of the high-k layer to the substrate. This may deteriorate the performance of the transistor in the CMIS.

### SUMMARY OF THE INVENTION

An embodiment of the present invention is, for example, a method of manufacturing a semiconductor device, for forming transistors of first and second conductivity types in first and second regions on a substrate respectively, the method including: depositing a gate insulator on the substrate, ranging from the first region to the second region; depositing a sacrificial layer on the gate insulator, ranging from the first region to the second region; removing the sacrificial layer from the first region by etching; depositing a first gate electrode layer, on the gate insulator exposed in the first region, and on the sacrificial layer remaining in the second region; removing the first gate electrode layer from the second region by etching; removing the sacrificial layer from the second region by etching; depositing a second gate electrode layer on the gate insulator exposed in the second region; processing the first gate electrode layer to form the transistor of the first conductivity type including the gate insulator and the first gate electrode layer; and processing the second gate electrode layer to form the transistor of the second conductivity type including the gate insulator and the second gate electrode layer.

Another embodiment of the present invention is, for example, a method of manufacturing a semiconductor device, for forming transistors of first and second conductivity types in first and second regions on a substrate respectively, the method including: depositing a sacrificial layer on the substrate, ranging from the first region to the second region; removing the sacrificial layer from the first region by etching; depositing a first gate insulator, on the substrate exposed in the first region, and on the sacrificial layer remaining in the second region; depositing a first gate electrode layer on the first gate insulator, ranging from the first region to the second region; removing the first gate electrode layer from the second region by etching; removing the first gate insulator from the second region by etching; removing the sacrificial layer from the second region by etching; depositing a second gate insulator on the substrate exposed in the second region; depositing a second gate electrode layer on the second gate insulator; processing the first gate electrode layer to form the transistor of the first conductivity type including the first gate insulator and the first gate electrode layer; and processing the second gate electrode layer to form the transistor of the second conductivity type including the second gate insulator and the second gate electrode layer.

### BRIEF DESCRIPTION OF THE DRAWINGS

FIG. 1 is a side sectional view of a semiconductor device according to a first embodiment;

FIGS. 2A to 2I illustrate a manufacturing process of the semiconductor device according to the first embodiment;

FIG. 3 is a side sectional view of a semiconductor device according to a second embodiment;

FIGS. 4A to 4L illustrate a manufacturing process of the semiconductor device according to the second embodiment;

FIG. 5 is a side sectional view of a semiconductor device according to a third embodiment;

FIGS. 6A to 6K illustrate a manufacturing process of the semiconductor device according to the third embodiment;

FIG. 7 is an enlarged view of a region X shown in FIG. 6E; and

FIG. 8 is an enlarged view of a region Y shown in FIG. 6H.

### DESCRIPTION OF THE EMBODIMENTS

### First Embodiment

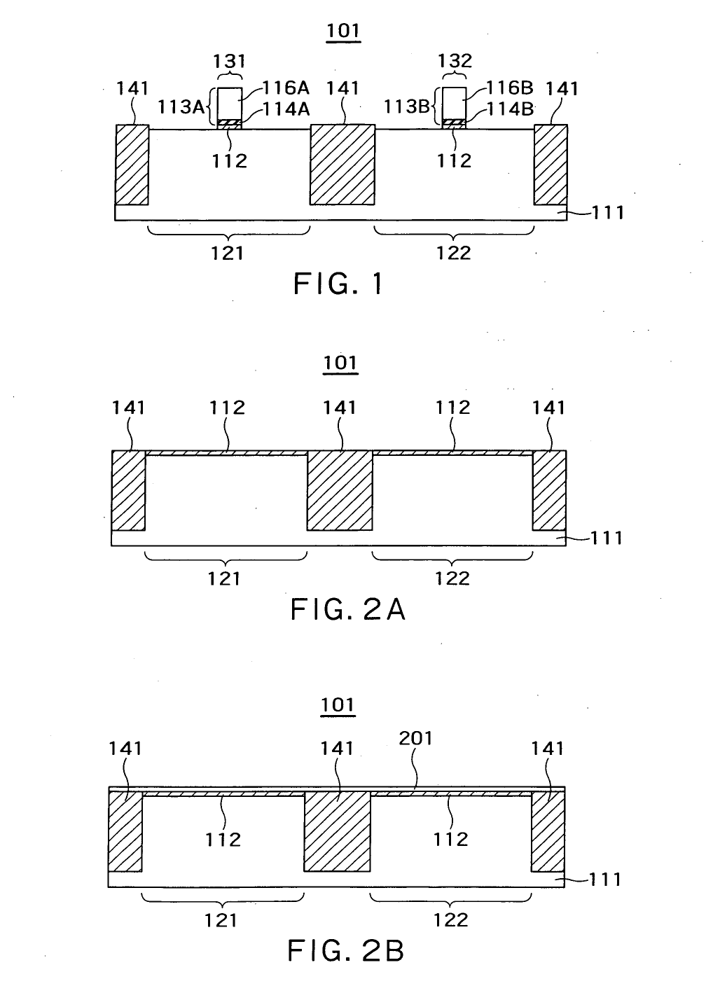

FIG. 1 is a side sectional view of a semiconductor device 101 according to a first embodiment. In the semiconductor device 101 in FIG. 1, an NMIS 131 and a PMIS 132 are formed in an NMIS region 121 and a PMIS region 122 on a substrate 111, respectively. One of the NMIS 131 and the PMIS 132 is an example of a transistor of a first conductivity type, and the other is an example of a transistor of a second conductivity type. Further, one of the NMIS region 121 and the PMIS region 122 is an example of a first region, and the other is an example of a second region. In this embodiment, it is assumed that the NMIS 131 is an example of the transistor of the first conductivity type and the PMIS 132 is an example of the transistor of the second conductivity type. Further, in this embodiment, it is assumed that the NMIS region 121 is an example of the first region and the PMIS region 122 is an example of the second region. The NMIS 131 and the PMIS 132 in this embodiment form a CMIS. The NMIS region 121 and the PMIS region 122 in this embodiment are separated from each other by an isolation layer 141, which is an STI layer.

The semiconductor device 101 in FIG. 1 includes the substrate 111, gate insulators 112, a first gate electrode 113A, and a second gate electrode 113B. The NMIS 131 includes the substrate 111, a gate insulator 112, and the first gate electrode 113A. The PMIS 132 includes the substrate 111, a gate insulator 112, and the second gate electrode 113B. The first gate electrode 113A includes a first gate electrode layer 114A, and a semiconductor layer 116A. The second gate electrode 113B includes a second gate electrode layer 114B, and a semiconductor layer 116B.

The substrate 111 in this embodiment is a semiconductor substrate formed of semiconductor, specifically, a silicon substrate formed of silicon. The gate insulators 112 are formed on the substrate 111. Each of the gate insulators 112 in this embodiment is an insulator formed of silicon oxide. The first gate electrode layer 114A is formed on the gate insulator 112. The first gate electrode layer 114A in this embodiment is a metal electrode layer including a metal layer. The second gate electrode layer 114B is formed on the gate insulator 112. The second gate electrode layer 114B in this embodiment is a metal electrode layer including a metal layer. In this embodiment, metal material of the first gate electrode layer 114A and metal material of the second gate electrode layer 114B are different materials, so that the work function of the first gate electrode layer 114A and the work function of the second gate electrode layer 114B are different. The semiconductor layers 116A and 116B are formed on the first and second gate electrode layers 114A and 114B, respectively. Each of the semiconductor layers 116A and 116B in this embodiment is a semiconductor electrode layer formed of semiconductor, specifically, a polysilicon electrode layer formed of polysilicon.

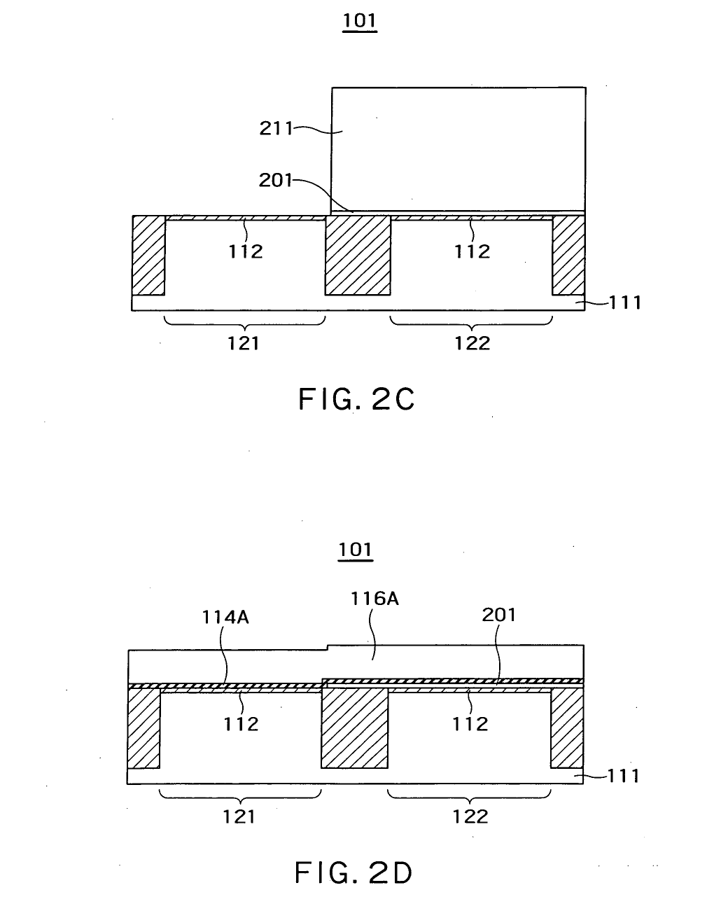

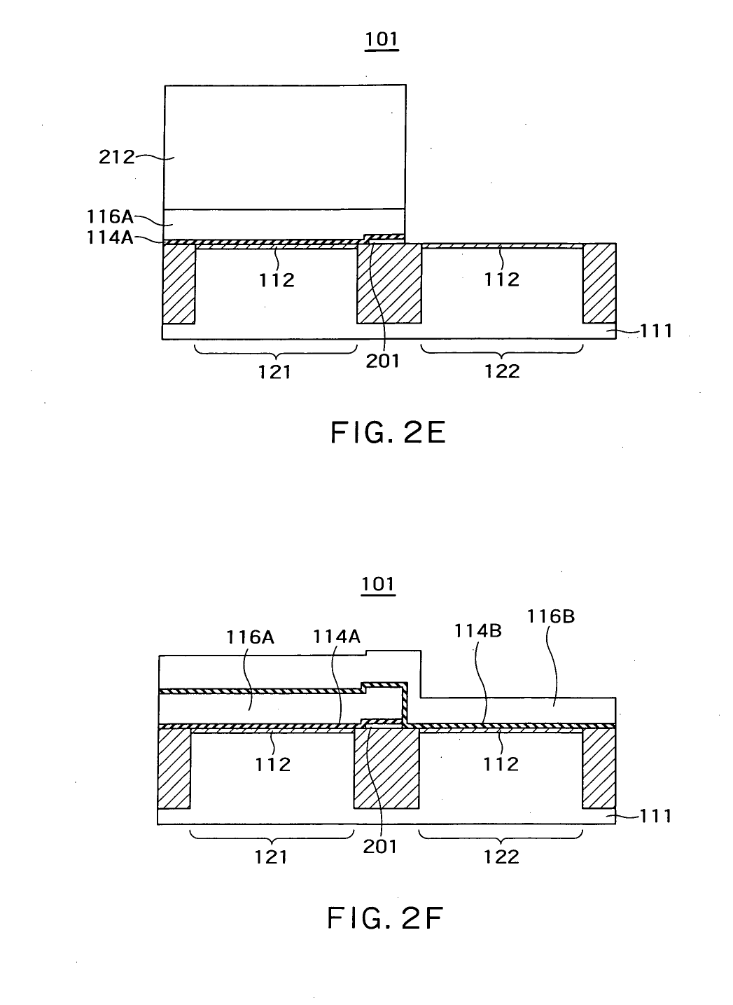

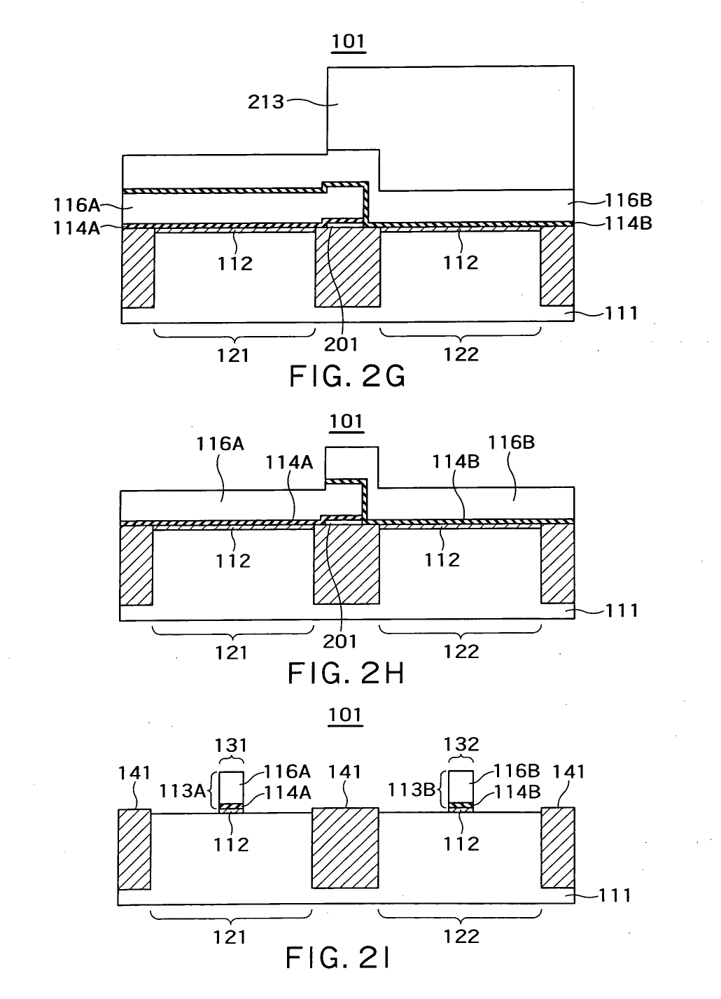

FIGS. 2A to 2I illustrate a manufacturing process of the semiconductor device 101 according to the first embodiment.

First, an isolation trench is formed on a substrate 111 by lithography and etching. Then, the surface of the isolation trench is oxidized to embed silicon oxide in the isolation trench. Consequently, an isolation layer 141 is formed on the substrate 111. Then, ion implantation into an NMIS region 121 and ion implantation into a PMIS region 122 are performed. Then, a gate insulator 112 of silicon oxide is deposited over the entire surface. Consequently, the gate insulator 112 is deposited on the substrate 111, ranging from the NMIS region 121 to the PMIS region 122 (FIG. 2A). That is, the gate insulator 112 is deposited in the NMIS region 121 and the PMIS region 122.

Next, a sacrificial layer 201 formed of material whose etching selectivity to the gate insulator 112 is easily obtained, is deposited over the entire surface. Consequently, the sacrificial layer 201 is deposited on the gate insulator 112, ranging from the NMIS region 121 to the PMIS region 122 (FIG. 2B). That is, the sacrificial layer 201 is deposited in the NMIS region 121 and the PMIS region 122.

The sacrificial layer 201 in this embodiment is formed of material whose etching selectivity to the gate insulator 112 can be equal to or higher than 10, preferably, equal to or higher than 100. For example, when a silicon oxide layer added with hafnium and nitrogen is adopted as the gate insulator 112, it is possible to realize the etching selectivity equal to or higher than 100, by adopting polysilicon as the material of the sacrificial layer 201. Examples of the gate insulator 112 in the case that the material of the sacrificial layer 201 is polysilicon, include a silicon oxide layer, a hafnium oxide layer, a silicon oxide layer added with hafnium, a silicon oxide layer added with nitrogen, a silicon oxide layer added with hafnium and nitrogen, and a laminated layer including two or more layers of said oxide layers. Consequently, in this embodiment, it is possible to remove the sacrificial layer 201 from the gate insulator 112, while preventing damage to the gate insulator 112 and over-etching of the gate insulator 112.

In this embodiment, it is assumed that the material of the sacrificial layer 201 is polysilicon. In other words, it is assumed that the sacrificial layer 201 is a polysilicon layer. The thickness of the sacrificial layer 201 in this embodiment is 5 to 30 nm. The sacrificial layer 201 in this embodiment is deposited by CVD (chemical vapor deposition).

Next, the PMIS region 122 is covered with a resist 211 by lithography. Then, the sacrificial layer 201 is selectively removed from the NMIS region 121 by etching (FIG. 2C). The etching may be isotropic etching, or may be anisotropic etching. In this embodiment, it is assumed that the etching is RIE (reactive ion etching). In this embodiment, the sacrificial layer 201 is removed from the NMIS region 121 under an etching condition that the etching selectivity of the sacrificial layer 201 to the gate insulator 112 is equal to or higher than 10, desirably, equal to or higher than 100. Consequently, in this embodiment, the sacrificial layer 201 is removed from the NMIS region 121, while damage to the gate insulator 112 and over-etching of the gate insulator 112 are prevented. Then, the resist 211 is removed.

An example of the etching condition for the sacrificial layer 201 is described. When dry etching is performed, break-through (BT), first main etching (ME1), second main etching (ME2), and over-etching (OE) may be performed sequentially under the etching condition described below. The BT is performed under a pressure of 5 mT in the atmosphere containing CF₄. The ME1 is performed under a pressure of 3 to 15 mT in the atmosphere containing HBr, Cl₂, SF₆, CHF₃, O₂, N₂, He, or Ar. The ME2 is performed under a pressure of 5 to 20 mT in the atmosphere containing HBr, Cl₂, O₂, or N₂. The OE is performed under a pressure of 50 to 100 mT in the atmosphere containing HBr, O₂, or N₂. As for the ME1 and ME2, the ME1 may be omitted. Only the OE may be performed as dry etching. On the other hand, when wet etching is performed, alkali solution such as NH₃ or choline may be used as chemical.

Next, a first gate electrode layer 114A formed of first metal material is deposited over the entire surface. Consequently, the first gate electrode layer 114A is deposited, on the gate insulator 112 exposed in the NMIS region 121, and on the sacrificial layer 201 remaining in the PMIS region 122. Then, a semiconductor layer 116A of polysilicon is deposited over the entire surface. Consequently, the semiconductor layer 116A is deposited on the first gate electrode layer 114A, ranging from the NMIS region 121 to the PMIS region 122 (FIG. 2D).

Examples of the metal material of the first gate electrode layer 114A include Ta, TaB, TaC, TaN, Ta₂N, TaSiN, TaTi, Ti, TiB, TiC, TiN, TiAlN, W, WB, WC, WN, WSiₓ, Pt, PtSi, PtWSi, Hf, HfB, HfN, HfSiₓ, Ir, Au, Ru, RuO₂, AlN, ZrC, YₓSi, ErₓSi_{y}, and NiₓSi_{y}. Furthermore, the examples also include NiₓSi_{y} added with B, NiₓSi_{y} added with BF₂, NiₓSi_{y} added with Sr, and NiₓSi_{y} added with Al. Desirable examples of the metal material of the first gate electrode layer 114A include TaC, TaN, TaSiN, TiN, and W.

Next, the NMIS region 121 is covered with a resist 212 by lithography. Then, the semiconductor layer 116A is selectively removed from the PMIS region 122 by etching. Then, the first gate electrode layer 114A is selectively removed from the PMIS region 122 by etching. Then, the sacrificial layer 201 is selectively removed from the PMIS region 122 by etching (FIG. 2E). Each of the etchings may be isotropic etching, or may be anisotropic etching. In this embodiment, it is assumed that each of the etchings is RIE (reactive ion etching). In this embodiment, the sacrificial layer 201 is removed from the PMIS region 122 under an etching condition that the etching selectivity of the sacrificial layer 201 to the gate insulator 112 is equal to or higher than 10, desirably, equal to or higher than 100. Consequently, in this embodiment, the sacrificial layer 201 is removed from the PMIS region 122, while damage to the gate insulator 112 and over-etching of the gate insulator 112 are prevented. Then, the resist 212 is removed.

An example of the etching condition for the sacrificial layer 201 is similar to the example of the etching condition described above. Here, an example of an etching condition for the first gate electrode layer 114A is described. An Example of the etching includes dry etching. Examples of an etching gas in this case include HBr, Cl₂, SF₆, CF₄, CHF₃, CH₄, BCl₃, NF₃, O₂, N₂, He, and Ar.

Next, a second gate electrode layer 114B formed of second metal material is deposited over the entire surface. Consequently, the second gate electrode layer 114B is deposited, on the semiconductor layer 116A remaining in the NMIS region 121, and on the gate insulator 112 exposed in the PMIS region 122. Then, a semiconductor layer 116B of polysilicon is deposited over the entire surface. Consequently, the semiconductor layer 116B is deposited on the second gate electrode layer 114B, ranging from the NMIS region 121 to the PMIS region 122 (FIG. 2F).

Examples of the metal material of the second gate electrode layer 114B include Ta, TaB, TaC, TaN, Ta₂N, TaSiN, TaTi, Ti, TiB, TiC, TiN, TiAlN, W, WB, WC, WN, WSiₓ, Pt, PtSi, PtWSi, Hf, HfB, HfN, HfSiₓ, Ir, Au, Ru, RuO₂, AlN, ZrC, YₓSi, ErₓSi_{y}, and NiₓSi_{y}. Furthermore, the examples also include NiₓSi_{y} added with B, NiₓSi_{y} added with BF₂, NiₓSi_{y} added with Sr, and NiₓSi_{y} added with Al. Desirable examples of the metal material of the second gate electrode layer 114B include TaC, TaN, TaSiN, TiN, and W. However, the metal material of the second gate electrode layer 114B is different from the metal material of the first gate electrode layer 114A.

Next, the PMIS region 122 is covered with a resist 213 by lithography (FIG. 2G). Then, the semiconductor layer 116B is selectively removed from the NMIS region 121 by etching. Then, the second gate electrode layer 114B is selectively removed from the NMIS region 121 by etching (FIG. 2H). Each of the etchings may be isotropic etching, or may be anisotropic etching. In this embodiment, it is assumed that each of the etchings is RIE (reactive ion etching).

An example of an etching condition for the second gate electrode layer 114B is similar to the example of the etching condition for the first gate electrode layer 114A.

Next, the first gate electrode layer 114A, the semiconductor layer 116A, the second gate electrode layer 114B, the semiconductor layer 116B and the like are processed by lithography and etching. Consequently, an NMIS 131 including the gate insulator 112, the first gate electrode layer 114A, and the semiconductor layer 116A is formed in the NMIS region 121. In addition, a PMIS 132 including the gate insulator 112, the second gate electrode layer 114B, and the semiconductor layer 116B is formed in the PMIS region 122 (FIG. 2I). Processing of the NMIS 131 (processing of the first gate electrode layer 114A and the like) and processing of the PMIS 132 (processing of the second gate electrode layer 114B and the like) may be performed collectively, or may be performed separately.

Thereafter, source and drain regions are formed in the substrate of the NMIS region 121 and the PMIS region 122. Subsequently, sidewall insulators are formed on sidewalls of the NMIS 131 and the PMIS 132. Subsequently, lines are formed by etching or damascene. In this way, the semiconductor device 101 is completed.

According to the manufacturing method described above, it is possible to remove the first gate electrode layer 114A from the PMIS region 122, while preventing damage to the gate insulator 112 and over-etching of the gate insulator 112 (see FIG. 2E). This is because the sacrificial layer 201, whose etching selectivity to the gate insulator 112 is easily obtained, is deposited between the gate insulator 112 and the first gate electrode layer 114A, in the PMIS region 122 (see FIG. 2D). Consequently, in this embodiment, it is possible to prevent deterioration in performance of the transistor due to removal of the gate electrode layer.

In this embodiment, the gate electrode layers are formed by depositing the gate electrode layer for the NMIS 131, and then depositing the gate electrode layer for the PMIS 132. However, the gate electrode layers may be formed by depositing the gate electrode layer for the PMIS 132, and then depositing the gate electrode layer for the NMIS 131.

In this embodiment, the gate insulator 112 is a silicon oxide layer. However, the gate insulator 112 may be a high-k layer (a high-permittivity insulating layer).

In this embodiment, each of the first and second gate electrode layers 114A and 114B is a metal electrode layer including one metal layer. However, each of the first and second gate electrode layers 114A and 114B may be a metal electrode layer including two or more metal layers. Examples of metal materials of the metal layers include two or more metal materials selected from Ta, TaB, TaC, TaN, Ta₂N, TaSiN, TaTi, Ti, TiB, TiC, TiN, TiAlN, W, WB, WC, WN, WSiₓ, Pt, PtSi, PtWSi, Hf, HfB, HfN, HfSiₓ, Ir, Au, Ru, RuO₂, AlN, ZrC, YₓSi, ErₓSi_{y}, NiₓSi_{y}, NiₓSi_{y} added with B, NiₓSi_{y} added with BF₂, NiₓSi_{y} added with Sr, and NiₓSi_{y} added with Al. Desirable examples of the metal materials of the metal layers include two or more metal materials selected from TaC, TaN, TaSiN, TiN, and W.

In this embodiment, the first and second gate electrodes 113A and 113B include the semiconductor layers 116A and 116B. However, the first and second gate electrodes 113A and 113B do not have to include the semiconductor layers 116A and 116B. Further, a barrier layer, which can prevent metal atoms contained in the first gate electrode layer 114A from moving to the semiconductor layer 116A, may be formed between the first gate electrode layer 114A and the semiconductor layer 116A. Further, a barrier layer, which can prevent metal atoms contained in the second gate electrode layer 114B from moving to the semiconductor layer 116B, may be formed between the second gate electrode layer 114B and the semiconductor layer 116B. In the first embodiment, the semiconductor layers 116A and 116B are formed of different deposited layers. However, as in second and third embodiments, the semiconductor layers 116A and 116B may be formed of the same deposited layer.

Second and third embodiments will be hereinafter explained. Since these embodiments are modifications of the first embodiment, differences from the first embodiment will be mainly explained.

### Second Embodiment

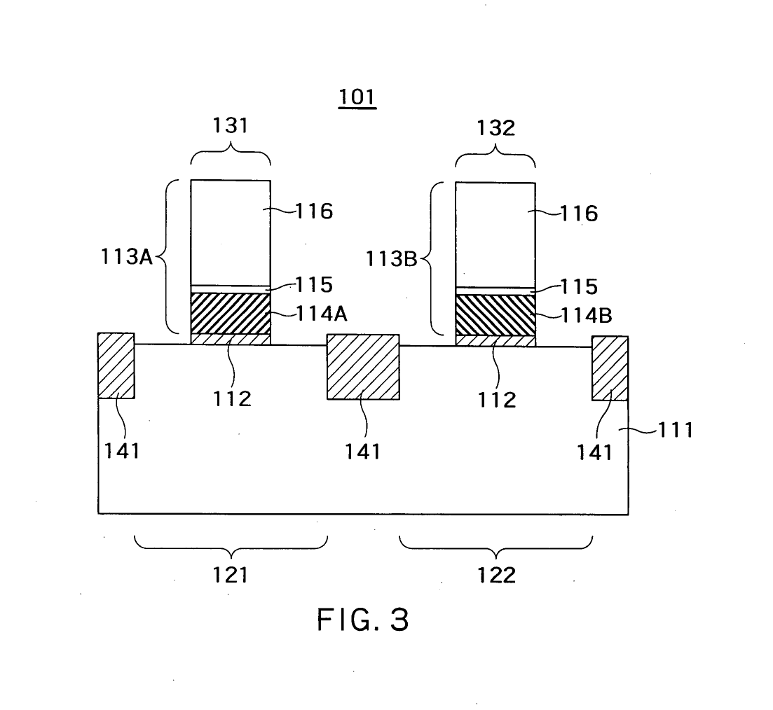

FIG. 3 is a side sectional view of a semiconductor device 101 according to a second embodiment. In the semiconductor device 101 in FIG. 3, an NMIS 131 and a PMIS 132 are formed in an NMIS region 121 and a PMIS region 122 on a substrate 111, respectively. The NMIS region 121 and the PMIS region 122 in this embodiment are separated from each other by an isolation layer 141.

The semiconductor device 101 in FIG. 3 includes the substrate 111, gate insulators 112, a first gate electrode 113A, and a second gate electrode 113B. The NMIS 131 includes the substrate 111, a gate insulator 112, and the first gate electrode 113A. The PMIS 132 includes the substrate 111, a gate insulator 112, and the second gate electrode 113B. The first gate electrode 113A includes a first gate electrode layer 114A, a barrier layer 115, and a semiconductor layer 116. The second gate electrode 113B includes a second gate electrode layer 114B, a barrier layer 115, and a semiconductor layer 116.

The barrier layers 115 are formed on the first and second gate electrode layers 114A and 114B. The barrier layers 115 are provided for preventing atoms contained in the first and second gate electrode layers 114 and 114B from moving to the semiconductor layers 116. Each of the barrier layers 115 in this embodiment is a barrier metal layer including one or more metal layers. In this embodiment, it is assumed that each of the barrier layers 115 is a TiN electrode layer formed of TiN (titanium nitride). The semiconductor layers 116 are formed on the barrier layers 115. Each of the semiconductor layers 116 in this embodiment is a semiconductor electrode layer formed of semiconductor, specifically, a polysilicon electrode layer formed of polysilicon.

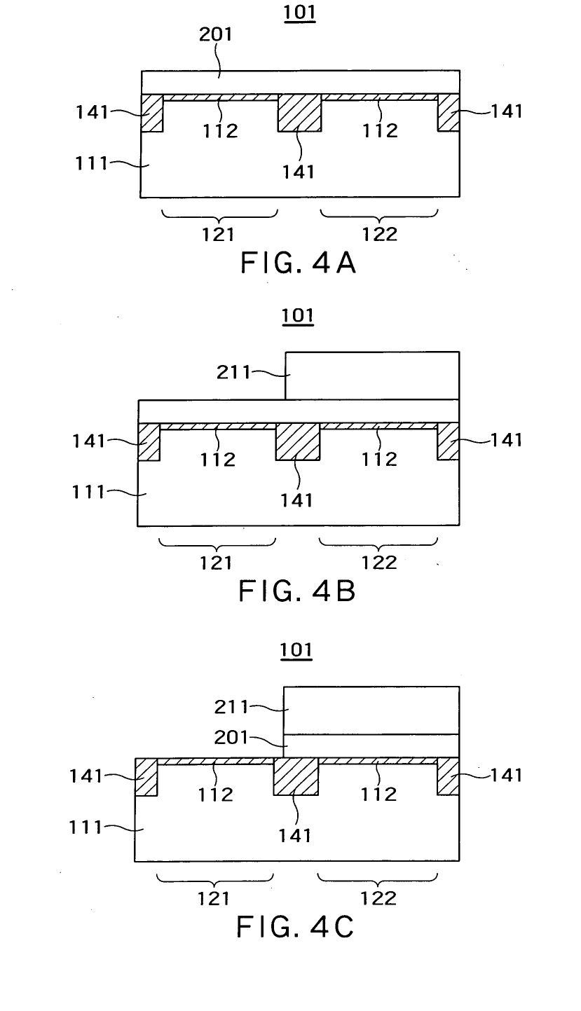

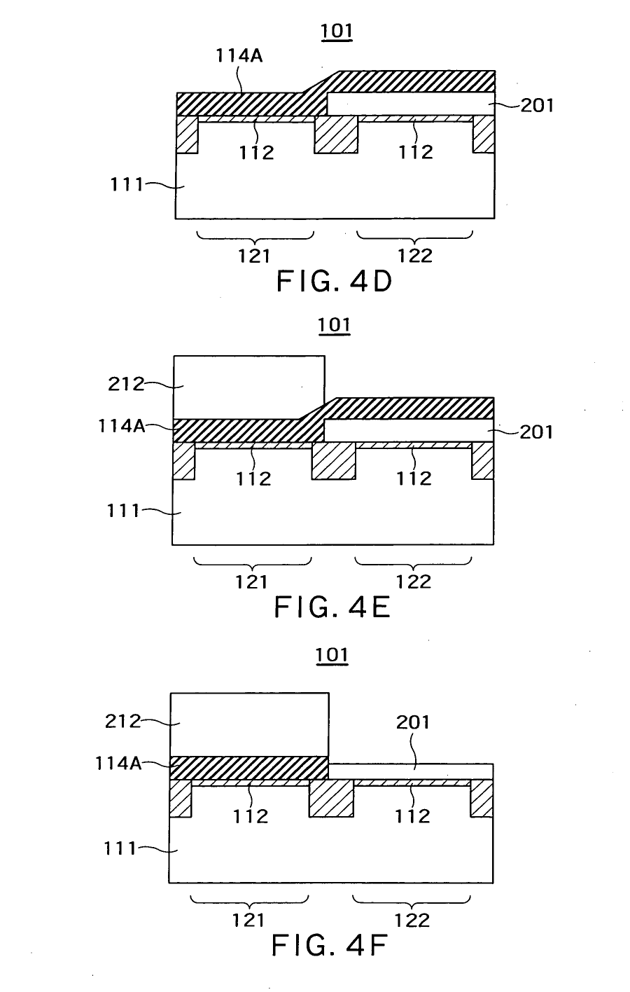

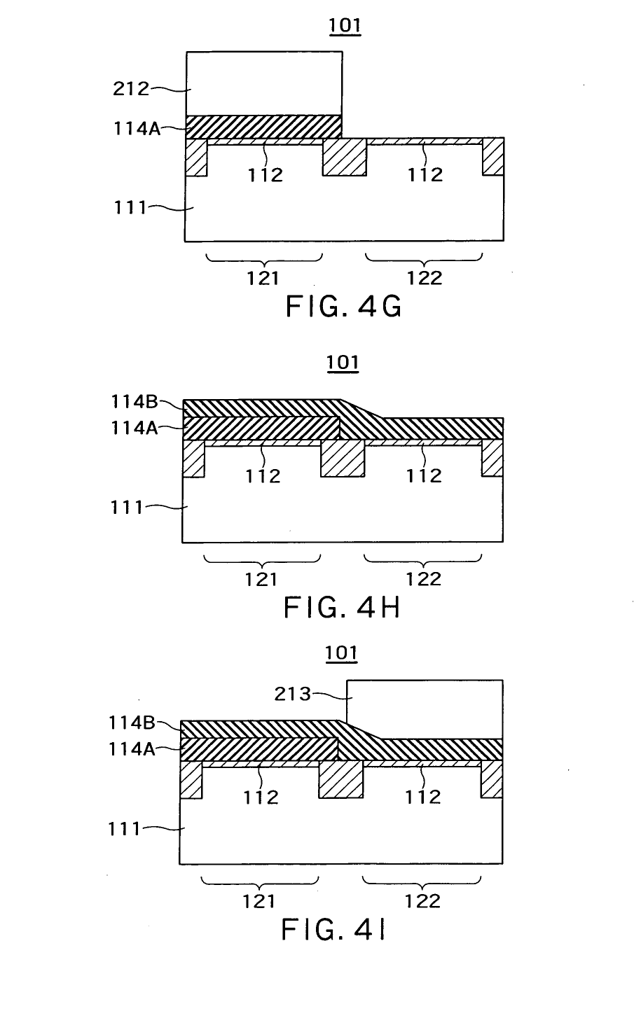

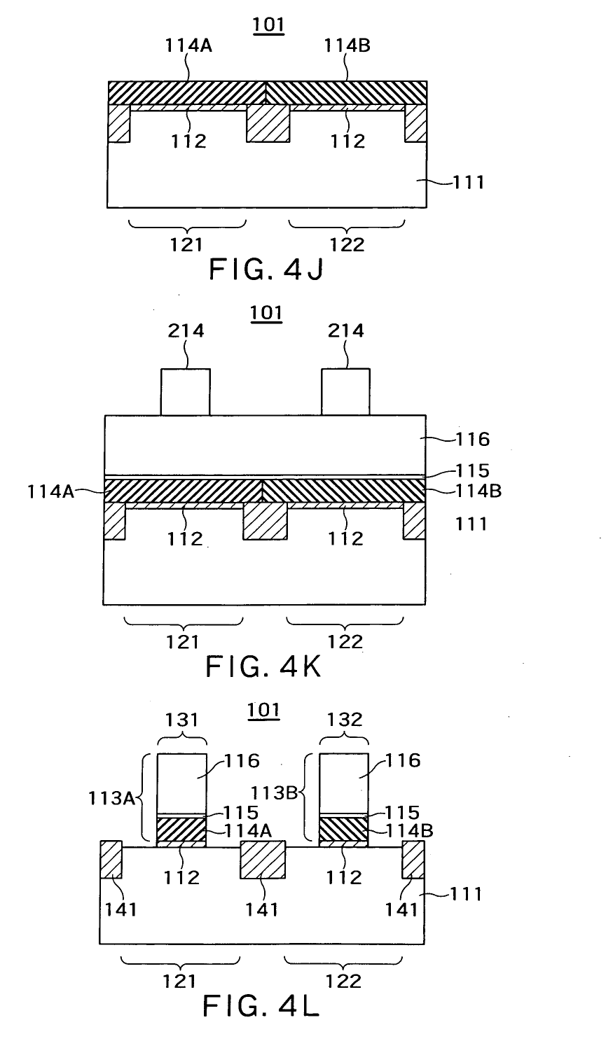

FIGS. 4A to 4L illustrate a manufacturing process of the semiconductor device 101 according to the second embodiment.

First, an isolation trench is formed on a substrate 111 by lithography and etching. Then, the surface of the isolation trench is oxidized to embed silicon oxide in the isolation trench. Consequently, an isolation layer 141 is formed on the substrate 111. Then, ion implantation into an NMIS region 121 and ion implantation into a PMIS region 122 are performed. Then, a gate insulator 112 of silicon oxide is deposited over the entire surface. Consequently, the gate insulator 112 is deposited on the substrate 111, ranging from the NMIS region 121 to the PMIS region 122. Then, a sacrificial layer 201 formed of material whose etching selectivity to the gate insulator 112 is easily obtained, is deposited over the entire surface. Consequently, the sacrificial layer 201 is deposited on the gate insulator 112, ranging from the NMIS region 121 to the PMIS region 122 (FIG. 4A).

In this embodiment, it is assumed that the material of the sacrificial layer 201 is polysilicon or amorphous silicon. In other words, it is assumed that the sacrificial layer 201 is a polysilicon layer or an amorphous silicon layer. The thickness of the sacrificial layer 201 in this embodiment is 5 to 30 nm. The sacrificial layer 201 in this embodiment is deposited by CVD (chemical vapor deposition).

Next, the PMIS region 122 is covered with a resist 211 by lithography (FIG. 4B). Then, the sacrificial layer 201 is selectively removed from the NMIS region 121 by etching (FIG. 4C). The etching may be isotropic etching, or may be anisotropic etching. In this embodiment, it is assumed that the etching is RIE. In this embodiment, the sacrificial layer 201 is removed from the NMIS region 121 under an etching condition that the etching selectivity of the sacrificial layer 201 to the gate insulator 112 is equal to or higher than 10, desirably, equal to or higher than 100. Consequently, in this embodiment, the sacrificial layer 201 is removed from the NMIS region 121, while damage to the gate insulator 112 and over-etching of the gate insulator 112 are prevented. Then, the resist 211 is removed.

Next, a first gate electrode layer 114A formed of first metal material is deposited over the entire surface. Consequently, the gate electrode layer 114A is deposited, on the gate insulator 112 exposed in the NMIS region 121, and on the sacrificial layer 201 remaining in the PMIS region 122 (FIG. 4D).

Next, the NMIS region 121 is covered with a resist 212 by lithography (FIG. 4E). Then, the first gate electrode layer 114A is selectively removed from the PMIS region 122 by etching (FIG. 4F). Then, the sacrificial layer 201 is selectively removed from the PMIS region 122 by etching (FIG. 4G). Each of the etchings may be isotropic etching, or may be anisotropic etching. In this embodiment, it is assumed that each of the etchings is RIE. In this embodiment, the sacrificial layer 201 is removed from the PMIS region 122 under an etching condition that the etching selectivity of the sacrificial layer 201 to the gate insulator 112 is equal to or higher than 10, desirably, equal to or higher than 100. Consequently, in this embodiment, the sacrificial layer 201 is removed from the PMIS region 122, while damage to the gate insulator 112 and over-etching of the gate insulator 112 are prevented. Then, the resist 212 is removed.

The sacrificial layer 201 may be removed from the PMIS region 122, by performing etching under an etching condition with a low etching selectivity, and then performing etching under an etching condition with a high etching selectivity. In this case, it is desirable that at least the latter etching is performed under the etching condition described above. According to the etching condition described above, the etching selectivity is equal to or higher than 10, or equal to or higher than 100. A state when the former etching is finished is shown in FIG. 4F.

Next, a second gate electrode layer 114B formed of second metal material is deposited over the entire surface. Consequently, the second gate electrode layer 114B is deposited, on the first gate electrode layer 114A remaining in the NMIS region 121, and on the gate insulator 112 exposed in the PMIS region 122 (FIG. 4H). The metal material of the second gate electrode layer 114B is different from the metal material of the first gate electrode layer 114A.

Next, the PMIS region 122 is covered with a resist 213 by lithography (FIG. 4I). Then, the second gate electrode layer 114B is selectively removed from the NMIS region 121 by etching (FIG. 43). The etching may be isotropic etching, or may be anisotropic etching. In this embodiment, it is assumed that the etching is RIE. The second gate electrode layer 114B does not have to be removed from the NMIS region 121 in some case.

Next, a barrier layer 115 of titanium nitride is deposited over the entire surface. Consequently, the barrier layer 115 is deposited, on the first gate electrode layer 114A of the NMIS region 121, and on the second gate electrode layer 114B of the PMIS region 122. Then, a semiconductor layer 116 of polysilicon is deposited over the entire surface. Consequently, the semiconductor layer 116 is deposited on the barrier layer 115, ranging from the NMIS region 121 to the PMIS region 122. Then, a resist 214 for forming transistors is formed by lithography (FIG. 4K).

Next, the first gate electrode layer 114A, the second gate electrode layer 114B, the barrier layer 115, the semiconductor layer 116 and the like are processed by etching. Consequently, an NMIS 131 including the gate insulator 112, the first gate electrode layer 114A, the barrier layer 115, and the semiconductor layer 116 is formed in the NMIS region 121. In addition, a PMIS 132 including the gate insulator 112, the second gate electrode layer 114B, the barrier layer 115, and the semiconductor layer 116 is formed in the PMIS region 122 (FIG. 4L). Processing of the NMIS 131 (processing of the first gate electrode layer 114A and the like) and processing of the PMIS 132 (processing of the second gate electrode layer 114B and the like) may be performed collectively, or may be performed separately.

Thereafter, source and drain regions are formed in the substrate of the NMIS region 121 and the PMIS region 122. Subsequently, sidewall insulators are formed on sidewalls of the NMIS 131 and the PMIS 132. Subsequently, lines are formed by etching or damascene. In this way, the semiconductor device 101 is completed.

According to the manufacturing method described above, it is possible to remove the first gate electrode layer 114A from the PMIS region 122, while preventing damage to the gate insulator 112 and over-etching of the gate insulator 112 (see FIG. 4F). This is because the sacrificial layer 201, whose etching selectivity to the gate insulator 112 is easily obtained, is deposited between the gate insulator 112 and the first gate electrode layer 114A, in the PMIS region 122 (see FIG. 4D). Consequently, in this embodiment, it is possible to prevent deterioration in performance of the transistor due to removal of the gate electrode layer.

In this embodiment, the gate electrode layers are formed by depositing the gate electrode layer for the NMIS 131, and then depositing the gate electrode layer for the PMIS 132. However, the gate electrode layers may be formed by depositing the gate electrode layer for the PMIS 132, and then depositing the gate electrode layer for the NMIS 131.

In this embodiment, the gate insulator 112 is a silicon oxide layer. However, the gate insulator 112 may be a high-k layer (a high-permittivity insulating layer).

In this embodiment, each of the first and second gate electrode layers 114A and 114B is a metal electrode layer including one metal layer. However, each of the first and second gate electrode layers 114A and 114B may be a metal electrode layer including two or more metal layers.

In this embodiment, the first and second gate electrodes 113A and 113B include the semiconductor layers 116. However, the first and second gate electrodes 113A and 113B do not have to include the semiconductor layers 116. Further, in this embodiment, the first and second gate electrodes 113A and 113B include the barrier layers 115. However, the first and second gate electrodes 113A and 113B do not have to include the barrier layers 115. In the second embodiment, the semiconductor layers 116 are formed of the same deposited layer. However, as in the first embodiment, the semiconductor layers 116 may be formed of different deposited layers. Further, in the second embodiment, the barrier layers 115 are formed of the same deposited layer. However, the barrier layers 115 may be formed of different deposited layers.

### Third Embodiment

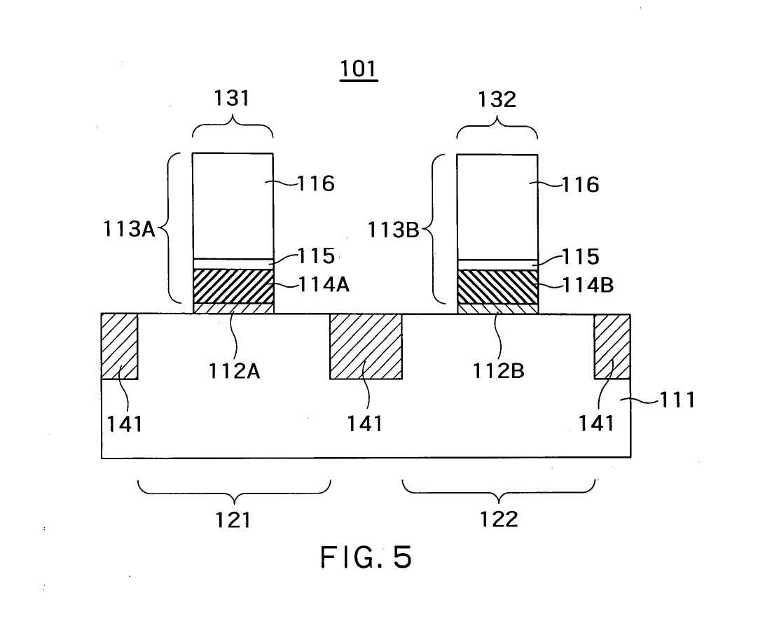

FIG. 5 is a side sectional view of a semiconductor device 101 according to a third embodiment. In the semiconductor device 101 in FIG. 5, an NMIS 131 and a PMIS 132 are formed in an NMIS region 121 and a PMIS region 122 on a substrate 111, respectively. The NMIS region 121 and the PMIS region 122 in this embodiment are separated from each other by an isolation layer 141.

The semiconductor device 101 in FIG. 5 includes the substrate 111, a first gate insulator 112A, a second gate insulator 112B, a first gate electrode 113A, and a second gate electrode 113B. The NMIS 131 includes the substrate 111, the first gate insulator 112A, and the first gate electrode 113A. The PMIS 132 includes the substrate 111, the second gate insulator 112B, and the second gate electrode 113B. The first gate electrode 113A includes a first gate electrode layer 114A, a barrier layer 115, and a semiconductor layer 116. The second gate electrode 113B includes a second gate electrode layer 114B, a barrier layer 115, and a semiconductor layer 116.

The first gate insulator 112A is formed on the substrate 111. The first gate insulator 112A in this embodiment is a high-k layer (a high-permittivity insulating layer). The second gate insulator 112B is formed on the substrate 111. The second gate insulator 112B in this embodiment is a high-k layer (a high-permittivity insulating layer). The first gate electrode layer 114A is formed on the first gate insulator 112A. The first gate electrode layer 114A in this embodiment is a metal electrode layer including a metal layer. The second gate electrode layer 114B is formed on the second gate insulator 112B. The second gate electrode layer 114B in this embodiment is a metal electrode layer including a metal layer. The barrier layers 115 are formed on the first and second gate electrode layers 114A and 114B. The barrier layers 115 are provided for preventing atoms contained in the first and second gate electrode layers 114A and 114B from moving to the semiconductor layers 116. Each of the barrier layers 115 in this embodiment is a barrier metal layer including one or more metal layers. In this embodiment, it is assumed that each of the barrier layers 115 is a TiN electrode layer formed of TiN (titanium nitride). The semiconductor layers 116 are formed on the barrier layers 115. Each of the semiconductor layers 116 in this embodiment is a semiconductor electrode layer formed of semiconductor, specifically, a polysilicon electrode formed of polysilicon.

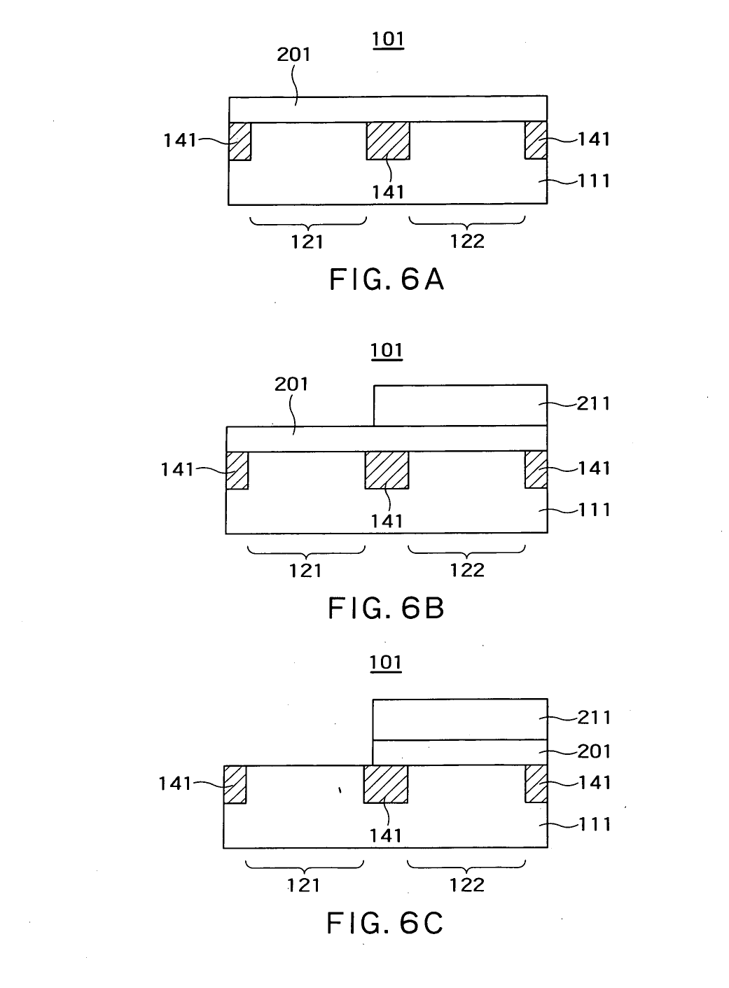

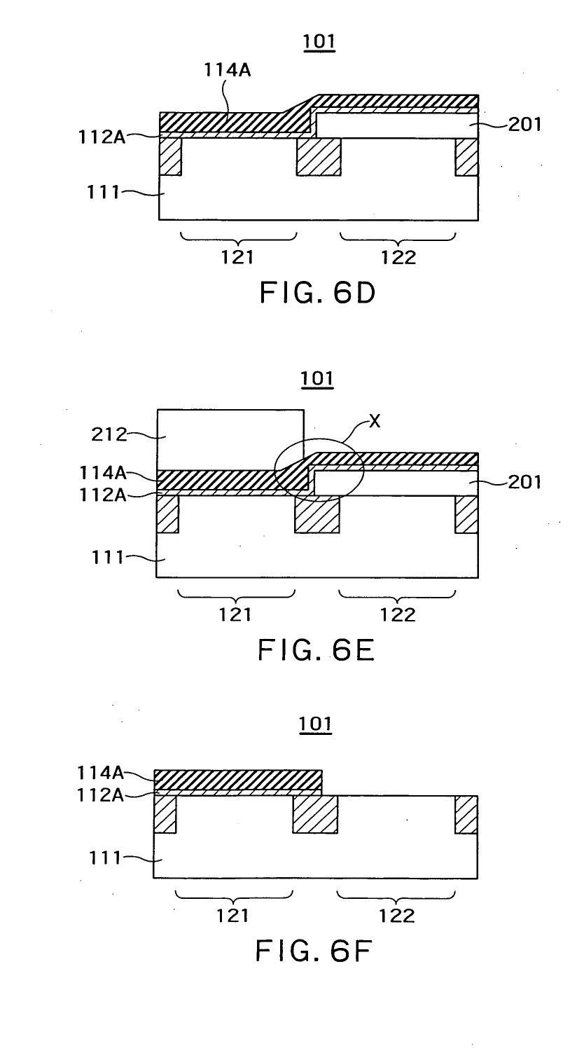

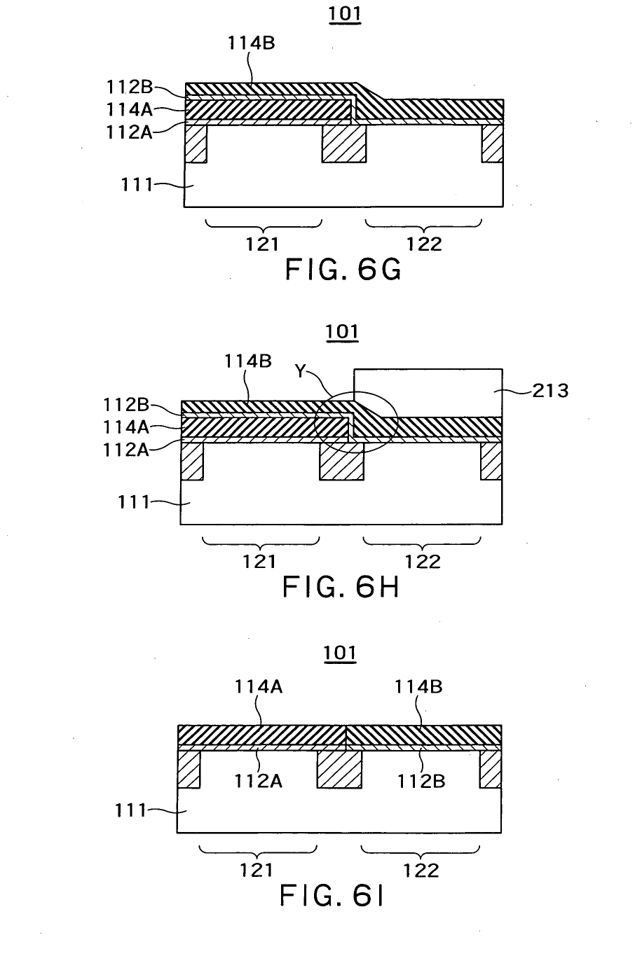

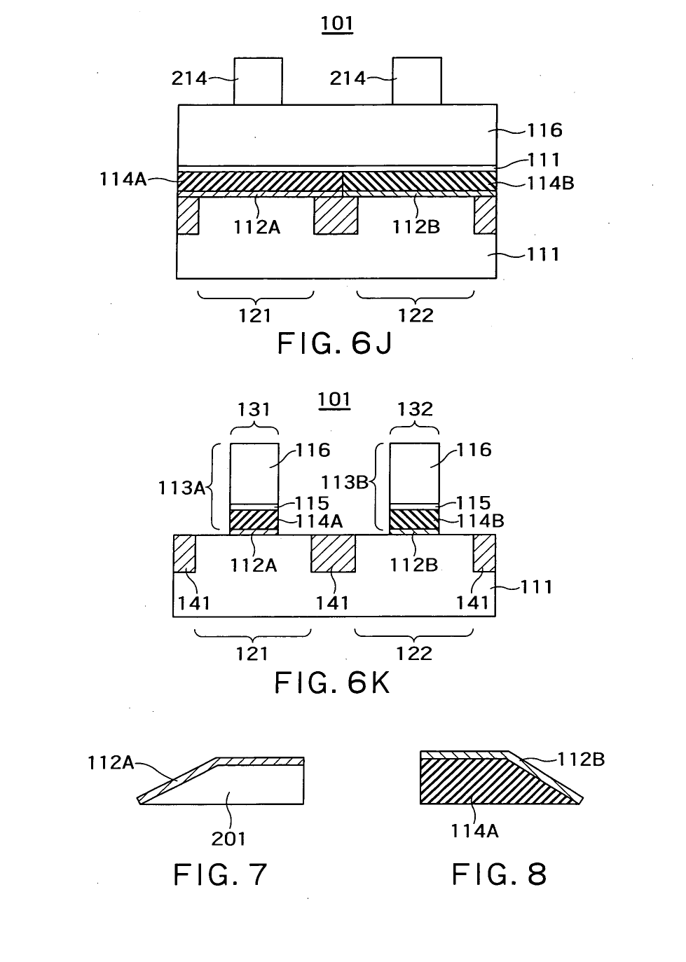

FIGS. 6A to 6K illustrate a manufacturing process of the semiconductor device 101 according to the third embodiment.

First, an isolation trench is formed on a substrate 111 by lithography and etching. Then, the surface of the isolation trench is oxidized to embed silicon oxide in the isolation trench. Consequently, an isolation layer 141 is formed on the substrate 111. Then, ion implantation into an NMIS region 121 and ion implantation into a PMIS region 122 are performed. Then, a sacrificial layer 201 formed of material whose etching selectivity to the substrate 111 is easily obtained, is deposited over the entire surface. Consequently, the sacrificial layer 201 is deposited on the substrate 111, ranging from the NMIS region 121 to the PMIS region 122 (FIG. 6A). That is, the sacrificial layer 201 is deposited in the NMIS region 121 and the PMIS region 122.

The sacrificial layer 201 in this embodiment is formed of material whose etching selectivity to the substrate 111 can be equal to or higher than 10. Consequently, in this embodiment, it is possible to remove the sacrificial layer 201 from the substrate 111, while preventing damage to the substrate 111 and over-etching of the substrate 111. In this embodiment, it is assumed that the material of the sacrificial layer 201 is oxide such as silicon oxide. In other words, it is assumed that the sacrificial layer 201 is an oxide layer such as a silicon oxide layer. The thickness of the sacrificial layer 201 in this embodiment is 5 to 30 nm. The sacrificial layer 201 in this embodiment is deposited by LPCVD (low pressure chemical vapor deposition).

Next, the PMIS region 122 is covered with a resist 211 by lithography (FIG. 6B). Then, the sacrificial layer 201 is selectively removed from the NMIS region 121 by etching (FIG. 6C). The etching may be isotropic etching, or may be anisotropic etching. In this embodiment, it is assumed that the etching is RIE. In this embodiment, the sacrificial layer 201 is removed from the NMIS region 121 under an etching condition that the etching selectivity of the sacrificial layer 201 to the substrate 111 is equal to or higher than 10. Consequently, in this embodiment, the sacrificial layer 201 is removed from the NMIS region 121, while damage to the substrate 111 and over-etching of the substrate 111 are prevented. Then, the resist 211 is removed.

An example of the etching condition for the sacrificial layer 201 is described. An example of the etching includes dry etching. Examples of an etching gas in this case include CH₄, CHF₃, CH₂F₂, C₄F₆, C₅F₈, O₂, and Ar. Pressure in the etching is, for example, 20 to 50 mT.

Next, a first gate insulator 112A formed of high-permittivity insulating material is deposited over the entire surface. Consequently, the first gate insulator 112A is deposited, on the substrate 111 exposed in the NMIS region 121, and on the sacrificial layer 201 remaining in the PMIS region 122. Then, a first gate electrode layer 114A formed of first metal material is deposited over the entire surface. Consequently, the first gate electrode layer 114A is deposited on the first gate insulator 112A, ranging from the NMIS region 121 to the PMIS region 122 (FIG. 6D). That is, the first gate electrode layer 114A is deposited in the NMIS region 121 and the PMIS region 122.

Examples of the high-permittivity insulating layer include a hafnium oxide layer, a silicon oxide layer added with hafnium, a silicon oxide layer added with hafnium and nitrogen, and a laminated layer including two or more layers of said oxide layers.

Next, the NMIS region 121 is covered with a resist 212 by lithography (FIG. 6E). Then, the first gate electrode layer 114A is selectively removed from the PMIS region 122 by etching. Then, the first gate insulator 112A is selectively removed from the PMIS region 122 by etching. Then, the sacrificial layer 201 is selectively removed from the PMIS region 122 by etching (FIG. 6F). Each of the etchings may be isotropic etching, or may be anisotropic etching. In this embodiment, it is assumed that each of the etchings is RIE. In this embodiment, the sacrificial layer 201 is removed from the PMIS region 122 under an etching condition that the etching selectivity of the sacrificial layer 201 to the substrate 111 is equal to or higher than 10. Consequently, in this embodiment, the sacrificial layer 201 is removed from the PMIS region 122, while damage to the substrate 111 and over-etching of the substrate 111 are prevented. Then, the resist 212 is removed.

An enlarged view of a region X in FIG. 6E is shown in FIG. 7. The region X is a boundary region. In order to make it easy to remove the first gate insulator 112A, an additional structure such as a taper structure is necessary, as shown in FIG. 7.

The sacrificial layer 201 may be removed from the PMIS region 122, by performing etching under an etching condition with a low etching selectivity, and then performing etching under an etching condition with a high etching selectivity. In this case, it is desirable that at least the latter etching is performed under the etching condition described above. According to the etching condition described above, the etching selectivity is equal to or higher than 10.

Next, a second gate insulator 112B formed of high-permittivity insulating material is deposited over the entire surface. Consequently, the second gate insulator 112B is deposited, on the first gate electrode layer 114A remaining on the NMIS region 121, and on the substrate 111 exposed in the PMIS region 122. Then, a second gate electrode layer 114B formed of second metal material is deposited over the entire surface. Consequently, the second gate electrode layer 114B is deposited on the second gate insulator 112B, ranging from the NMIS region 121 to the PMIS region 122 (FIG. 6G). The metal material of the second gate electrode layer 114B is different from the metal material of the first gate electrode layer 114A.

Examples of the high-permittivity insulating layer include a hafnium oxide layer, a silicon oxide layer added with hafnium, a silicon oxide layer added with hafnium and nitrogen, and a laminated layer including two or more layers of said oxide layers.

Next, the PMIS region 122 is covered with a resist 213 by lithography (FIG. 6H). Then, the second gate electrode layer 114B is selectively removed from the NMIS region 121 by etching. Then, the second gate insulator 112B is selectively removed from the NMIS region 121 by etching (FIG. 6I). Each of the etchings may be isotropic etching, or may be anisotropic etching. In this embodiment, it is assumed that each of the etchings is RIE. The second gate electrode layer 114B does not have to be removed from the NMIS region 121 in some case.

An enlarged view of a region Y in FIG. 6H is shown in FIG. 8. The region Y is a boundary region. In order to make it easy to remove the second gate insulator 112B, an additional structure such as a taper structure is necessary, as shown in FIG. 8.

Next, a barrier layer 115 of titanium nitride is deposited over the entire surface. Consequently, the barrier layer 115 is deposited, on the first gate electrode layer 114A of the NMIS region 121, and on the second gate electrode layer 114B of the PMIS region 122. Then, a semiconductor layer 116 of polysilicon is deposited over the entire surface. Consequently, the semiconductor layer 116 is deposited on the barrier layer 115, ranging from the NMIS region 121 to the PMIS region 122. Then, a resist 214 for forming transistors is formed by lithography (FIG. 6J).

Next, the first gate electrode layer 114A, the second gate electrode layer 114B, the barrier layer 115, the semiconductor layer 116 and the like are processed by etching. Consequently, an NMIS 131 including the first gate insulator 112A, the first gate electrode layer 114A, the barrier layer 115, and the semiconductor layer 116 is formed in the NMIS region 121. In addition, a PMIS 132 including the second gate insulator 112B, the second gate electrode layer 114B, the barrier layer 115, and the semiconductor layer 116 is formed in the PMIS region 122 (FIG. 6K). Processing of the NMIS 131 (processing of the first gate electrode layer 114A and the like) and processing of the PMIS 132 (processing of the second gate electrode layer 114B and the like) may be performed collectively, or may be performed separately.

Thereafter, source and drain regions are formed in the substrate of the NMIS region 121 and the PMIS region 122. Subsequently, sidewall insulators are formed on sidewalls of the NMIS 131 and the PMIS 132. Subsequently, lines are formed by etching or damascene. In this way, the semiconductor device 101 is completed.

According to the manufacturing method described above, it is possible to remove the first gate insulator 112A from the PMIS region 122, while preventing damage to the substrate 111 and over-etching of the substrate 111 (see FIG. 6F). This is because the sacrificial layer 201, whose etching selectivity to the substrate 111 is easily obtained, is deposited between the substrate 111 and the first gate insulator 112A, in the PMIS region 122 (see FIG. 6D). Consequently, in this embodiment, it is possible to prevent deterioration in performance of the transistor due to removal of the gate insulator.

In this embodiment, the gate insulators and the gate electrode layers are formed by depositing the gate insulator and the gate electrode layer for the NMIS 131, and then depositing the gate insulator and the gate electrode layer for the PMIS 132. However, the gate insulators and the date electrode layers may be formed by depositing the gate insulator and the gate electrode layer for the PMIS 132, and then depositing the gate insulator and the gate electrode layer for the NMIS 131.

In this embodiment, each of the first and second gate insulators 112A and 112B is a high-k layer. However, each of the first and second gate insulators 112A and 112B may be an insulator other than a high-k layer.

In this embodiment, each of the first and second gate electrode layers 114A and 114B is a metal electrode layer including one metal layer. However, each of the first and second gate electrode layers 114A and 114B may be a metal electrode layer including two or more metal layers. Further, one or both of the first and second gate electrode layers 114A and 114B may be an electrode layer(s) other than a metal electrode layer(s).

In this embodiment, the first and second gate electrodes 113A and 113B include the semiconductor layers 116. However, the first and second gate electrodes 113A and 113B do not have to include the semiconductor layers 116. Further, in this embodiment, the first and second gate electrodes 113A and 113B include the barrier layers 115. However, the first and second gate electrodes 113A and 113B do not have to include the barrier layers 115. In the third embodiment, the semiconductor layers 116 are formed of the same deposited layer. However, as in the first embodiment, the semiconductor layers 116 may be formed of different deposited layers. Further, in the third embodiment, the barrier layers 115 are formed of the same deposited layer. However, the barrier layers 115 may be formed of different deposited layers.

There are provided the embodiments of the present invention, with regard to a method of manufacturing a semiconductor device. These embodiments relate to a method for forming transistors of first and second conductivity types, in first and second regions on a substrate respectively. As described above, these embodiments make it possible to prevent deterioration in performance of a transistor due to removal of a gate electrode layer or a gate insulator.

1. A method of manufacturing a semiconductor device, for forming transistors of first and second conductivity types in first and second regions on a substrate respectively, the method comprising:
depositing a gate insulator on the substrate, ranging from the first region to the second region;
depositing a sacrificial layer on the gate insulator, ranging from the first region to the second region;
removing the sacrificial layer from the first region by etching;
depositing a first gate electrode layer, on the gate insulator exposed in the first region, and on the sacrificial layer remaining in the second region;
removing the first gate electrode layer from the second region by etching;
removing the sacrificial layer from the second region by etching;
depositing a second gate electrode layer on the gate insulator exposed in the second region;
processing the first gate electrode layer to form the transistor of the first conductivity type including the gate insulator and the first gate electrode layer; and
processing the second gate electrode layer to form the transistor of the second conductivity type including the gate insulator and the second gate electrode layer.

2. The method according to claim 1, wherein
the transistor of the first conductivity type includes:
the gate insulator;
the first gate electrode layer including one or more metal layers; and
a semiconductor layer formed on the first gate electrode layer, and
the transistor of the second conductivity type includes:
the gate insulator;
the second gate electrode layer including one or more metal layers; and
a semiconductor layer formed on the second gate electrode layer.

3. The method according to claim 1, wherein
the transistor of the first conductivity type includes:
the gate insulator;
the first gate electrode layer including one or more metal layers;
a barrier layer formed on the first gate electrode layer; and
a semiconductor layer formed on the barrier layer, and
the transistor of the second conductivity type includes:
the gate insulator;
the second gate electrode layer including one or more metal layers;
a barrier layer formed on the second gate electrode layer; and
a semiconductor layer formed on the barrier layer.

4. The method according to claim 2, wherein
the first gate electrode layer includes a metal layer,
the second gate electrode layer includes a metal layer, and
material of the metal layer included in the first gate electrode layer and material of the metal layer included in the second gate electrode layer are different materials.

5. The method according to claim 2, wherein
the first gate electrode layer includes one or more layers of a W layer, a TiN layer, a TaC layer, a TaN layer, and a TaSiN layer, as the one or more metal layers, and
the second gate electrode layer includes one or more layers of a W layer, a TiN layer, a TaC layer, a TaN layer, and a TaSiN layer, as the one or more metal layers.

6. The method according to claim 1, wherein the sacrificial layer is removed from the first and second regions, by etching under an etching condition that the etching selectivity of the sacrificial layer to the gate insulator is equal to or higher than 10.

7. The method according to claim 1, wherein the thickness of the sacrificial layer is 5 to 30 nm.

8. The method according to claim 1, wherein the sacrificial layer is a polysilicon layer or an amorphous silicon layer.

9. The method according to claim 1, wherein the gate insulator is a silicon oxide layer, a hafnium oxide layer, a silicon oxide layer added with hafnium, a silicon oxide layer added with nitrogen, a silicon oxide layer added with hafnium and nitrogen, or a laminated layer including two or more layers of said oxide layers.

10. The method according to claim 1, wherein the gate insulator is a high-k layer.

11. A method of manufacturing a semiconductor device, for forming transistors of first and second conductivity types in first and second regions on a substrate respectively, the method comprising:
depositing a sacrificial layer on the substrate, ranging from the first region to the second region;
removing the sacrificial layer from the first region by etching;
depositing a first gate insulator, on the substrate exposed in the first region, and on the sacrificial layer remaining in the second region;
depositing a first gate electrode layer on the first gate insulator, ranging from the first region to the second region;
removing the first gate electrode layer from the second region by etching;
removing the first gate insulator from the second region by etching;
removing the sacrificial layer from the second region by etching;
depositing a second gate insulator on the substrate exposed in the second region;
depositing a second gate electrode layer on the second gate insulator;
processing the first gate electrode layer to form the transistor of the first conductivity type including the first gate insulator and the first gate electrode layer; and
processing the second gate electrode layer to form the transistor of the second conductivity type including the second gate insulator and the second gate electrode layer.

12. The method according to claim 11, wherein
the transistor of the first conductivity type includes:
the first gate insulator;
the first gate electrode layer including one or more metal layers; and
a semiconductor layer formed on the first gate electrode layer, and
the transistor of the second conductivity type includes:
the second gate insulator;
the second gate electrode layer including one or more metal layers; and
a semiconductor layer formed on the second gate electrode layer.

13. The method according to claim 11, wherein
the transistor of the first conductivity type includes:
the first gate insulator;
the first gate electrode layer including one or more metal layers;
a barrier layer formed on the first gate electrode layer; and
a semiconductor layer formed on the barrier layer, and
the transistor of the second conductivity type includes:
the second gate insulator;
the second gate electrode layer including one or more metal layers;
a barrier layer formed on the second gate electrode layer; and
a semiconductor layer formed on the barrier layer.

14. The method according to claim 12, wherein
the first gate electrode layer includes a metal layer,
the second gate electrode layer includes a metal layer, and
material of the metal layer included in the first gate electrode layer and material of the metal layer included in the second gate electrode layer are different materials.

15. The method according to claim 12, wherein
the first gate electrode layer includes one or more layers of a W layer, a TiN layer, a TaC layer, a TaN layer, and a TaSiN layer, as the one or more metal layers, and
the second gate electrode layer includes one or more layers of a W layer, a TiN layer, a TaC layer, a TaN layer, and a TaSiN layer, as the one or more metal layers.

16. The method according to claim 11, wherein the sacrificial layer is removed from the first and second regions, by etching under an etching condition that the etching selectivity of the sacrificial layer to the substrate is equal to or higher than 10.

17. The method according to claim 11, wherein the thickness of the sacrificial layer is 5 to 30 nm.

18. The method according to claim 11, wherein the sacrificial layer is a silicon oxide layer.

19. The method according to claim 11, wherein
the first gate insulator is a hafnium oxide layer, a silicon oxide layer added with hafnium, a silicon oxide layer added with hafnium and nitrogen, or a laminated layer including two or more layers of said oxide layers, and
the second gate insulator is a hafnium oxide layer, a silicon oxide layer added with hafnium, a silicon oxide layer added with hafnium and nitrogen, or a laminated layer including two or more layers of said oxide layers.

20. The method according to claim 11, wherein the first gate insulator is a high-k layer, and the second gate insulator is a high-k layer.
